(19) United States
(12) Patent Application Publication
(10) Pub. No.: US 2011/0159415 A1
(43) Pub. Date: Jun. 30, 2011

(54) ETCHING APPARATUS AND METHOD FOR FABRICATING ALTERNATING PHASE SHIFT MASK USING THE SAME

(75) Inventor: Sang Jin JO, Cheongju-si (KR)

(73) Assignee: HYNIX SEMICONDUCTOR INC., Icheon-si (KR)

(21) Appl. No.: 12/979,520

(22) Filed: Dec. 28, 2010

(30) Foreign Application Priority Data
Dec. 30, 2009 (KR) 10-2009-0134650

(51) Int. Cl. G03F 1/00; C23F 1/08

(52) U.S. Cl. 430/5; 156/345.24

(57) ABSTRACT

An etching apparatus includes: an etching space including a chamber; a chuck in the chamber and on which a transparent object to be etched can be loaded; a light source configured to irradiate light onto the object to be etched in order to detect a degree of etching of the object to be etched; and a detector configured to detect an intensity of the light having transmitted through the object to be etched after being emitted from the light source.

### CROSS-REFERENCES TO RELATED APPLICATIONS

The present application claims priority under 35 U.S.C 119(a) to Korean application number 10-2009-0134650, filed on Dec. 30, 2009, in the Korean intellectual property Office, which is incorporated herein by reference in its entirety.

### BACKGROUND

Exemplary embodiments of the present invention relate generally to fabricating a photomask, and more particularly to fabricating an alternating phase shift mask.

For higher integration and density, various technologies have been developed to form finer patterns in manufacturing semiconductor devices. One technique to improve the resolution of a photolithography process is by using patterns of a mask, more particularly, a method for exposing patterns by using a phase shift mask including a phase shifter. The phase shift mask exposes patterns with a desired size by using interference or partial interference of light, thereby increasing the resolution or focal depth. When light passes through a mask substrate, phase difference in the light occurs when a phase shifter is used such that the light that has passed through a shifter would have an inverse phase. The phase of the light passing through only a transmitting part is inverse to the phase of the light passing through the shifter located at an edge of the mask pattern. Accordingly, the intensity of light is offset at the boundary of the patterns and thus the resolution is increased.

When using a phase shift mask, the resolution of a mask can be improved by about 30% only by changing a mask in a conventional fine pattern formation method and without having to add new equipment. In this regard, the phase shift mask is considered as a powerful tool of the mass production technology for fabricating the next generation semiconductor devices. One example of the phase shift mask using such a principle is an alternating phase shift mask.

An alternating phase shift mask includes a transparent substrate and a plurality of phase shift patterns that were formed by etching the substrate.

The transparent substrate of an alternating phase shift mask is prepared to allow light to transmit therethrough, and the phase shift patterns are formed by etching the substrate to a predetermined depth to shift the phase of the light transmitted therethrough.

However, it is difficult to determine whether the substrate has been accurately etched until all processes after the etching process are completed. A conventional optical emission spectroscopy (OES) method may be used to check the etched depth of the substrate, but the conventional optical emission spectroscopy method is not effective when a mask includes material layers substantially identical to each other as with the alternating phase shift mask.

The optical emission spectroscopy method determines the determination of the etching process by detecting light with a different wavelength irradiated through reaction with plasma when the etching process is performed in a multi-layer structure including material layers different from each other. When etching a single quartz substrate, no change occurs in a wavelength emitted from plasma because there is no reaction between materials. That is, since only light with a wavelength caused by reaction between the substrate and the quartz is detected, it may be impossible to determine an etched depth of the substrate.

### SUMMARY

An embodiment of the present invention relates to an etching apparatus capable of etching a substrate by an accurate depth to form a phase shift pattern, and a method for fabricating an alternating phase shift mask.

In an embodiment of the present invention, an etching apparatus includes: a chamber configured to provide an etching space; a chuck installed in the chamber and on which a transparent object to be etched is loaded; a light source configured to irradiate light onto the object to be etched in order to detect a degree of etching of the object to be etched; and a detector configured to detect an intensity of the light having transmitted through the object to be etched after being emitted from the light source.

In another embodiment of the present invention, a method for fabricating an alternating phase shift mask includes: forming a hard mask pattern over a mask substrate to define a phase shift pattern; loading the mask substrate in an etching chamber, the etching chamber including a light source installed at one side of the mask substrate, and a detector installed at the other side thereof to detect light having transmitted through the mask substrate after being irradiated from the light source; and forming the phase shift pattern by etching the mask substrate by a predetermined depth while detecting the light having transmitted through the mask substrate after being irradiated from the light source.

### BRIEF DESCRIPTION OF THE DRAWINGS

The above and other aspects, features and other advantages will be more clearly understood from the following detailed description taken in conjunction with the accompanying drawings, in which:

FIG. 1 is a cross-sectional view illustrating an alternating phase shift mask;

FIG. 2 is a diagram schematically illustrating an etching apparatus used for fabricating a mask according to an embodiment of the present invention; and

FIGS. 3 to 6 are cross-sectional views illustrating a method for fabricating an alternating phase shift mask according to an embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

The embodiments of the present invention is directed to, inter alia, providing a technology capable of accurately controlling an etched depth of a substrate for forming an alternating phase shift pattern.

An optical emission spectroscopy (OES) method has difficulty in determining an etched depth of a quartz substrate because no change occurs in a wavelength emitted from plasma when etching the quartz substrate to form a phase shifter. An embodiment of the present invention provides a method, which automatically maintains an etch ending point at an appropriate level by using light transmittance of quartz constituting a mask substrate, extinction coefficient characteristics shown when light transmits through an interface, and scattering and extinction characteristics shown when light is incident into the interface, and an etching apparatus used for the same.

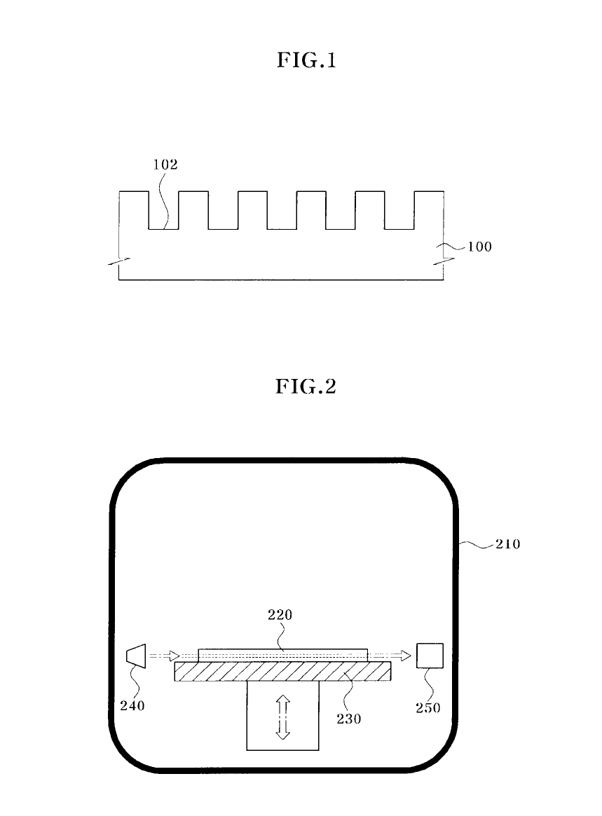

FIG. 1 is a cross-sectional view illustrating a general alternating phase shift mask.

Referring to FIG. 1, a transparent substrate 100 is prepared to allow light to transmit therethrough, and phase shift patterns 102 are formed by etching the substrate 100 by a predetermined depth to shift the phase of the light transmitted therethrough.

In order to fabricate the alternating phase shift mask, the quartz substrate 100 is coated with an opaque layer and a resist serving as a mask, and is subjected to exposure and development processes using electronic beam to form resist patterns. Then, the opaque layer is etched by using the resist patterns as an etching mask, and the substrate 100 is etched by a predetermined depth by using the etched opaque layer as a mask to form the phase shift patterns 102.

Since the patterns 102 are made of the same material as the transparent substrate 100, phase shift is completely dependent of the phase of light. In this regard, in order to meet finer patterns and tight conditions for the phase shift, a technology for etching a substrate by an accurate depth to form the phase shift pattern is very important. Particularly, it is very difficult and important to determine an etched depth of the substrate in-situ during the etching process, and to perform the etching process with high accuracy.

The conventional optical emission spectroscopy (OES) method used to check the etched depth of the substrate is not effective when a mask includes material layers substantially identical to each other as with the alternating phase shift mask (although the optical emission spectroscopy method may be effective when a mask includes material layers different from each other).

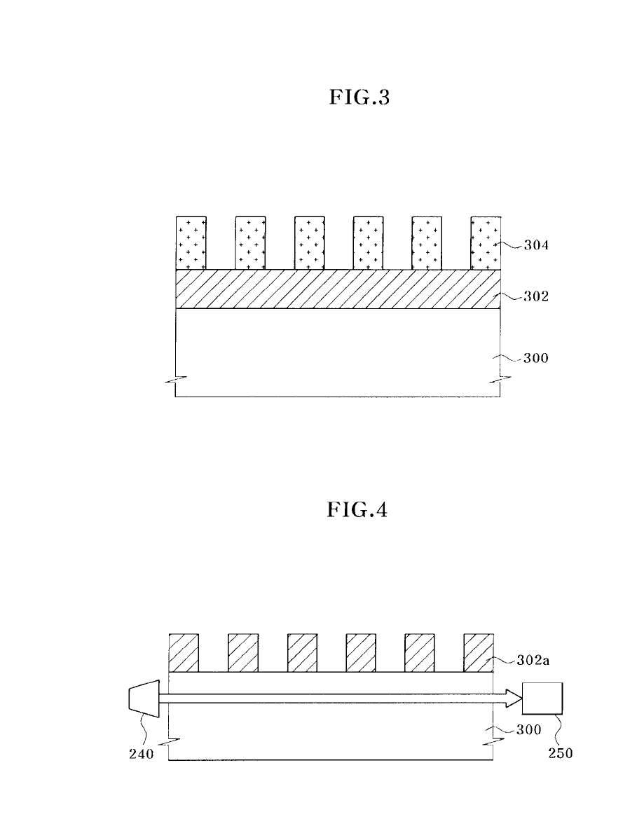

FIG. 2 is a diagram schematically illustrating an etching apparatus according to an embodiment of the present invention.

The etching apparatus according to an embodiment of the present invention includes a chamber 210 that provides an etching space, a chuck 230 installed inside the chamber 210 and on which a transparent object 220 to be etched is loaded, a light source 240 that irradiates light onto the object 220 to be etched in order to detect the degree of etching of the object 220 to be etched, and a detector 250 that detects the intensity of the light having transmitted through the object 220 to be etched after being emitted from the light source 240.

The object 220 to be etched is made of a transparent material capable of allowing the light emitted from the light source 240 to transmit therethrough, and may include a quartz substrate for a photomask. The light source 240 and the detector 250 are installed at a position which is equal to or lower than the target etching depth of the object 220 to be etched.

When the etched depth of the object 220 exceeds the position at which the light emitted from the light source 240 transmits through the transparent object 220 to be etched, and change in the intensity of the light detected by the detector 250 reaches a predetermined level, an etch ending point is determined and controlled, so that the etched depth can be controlled with accuracy.

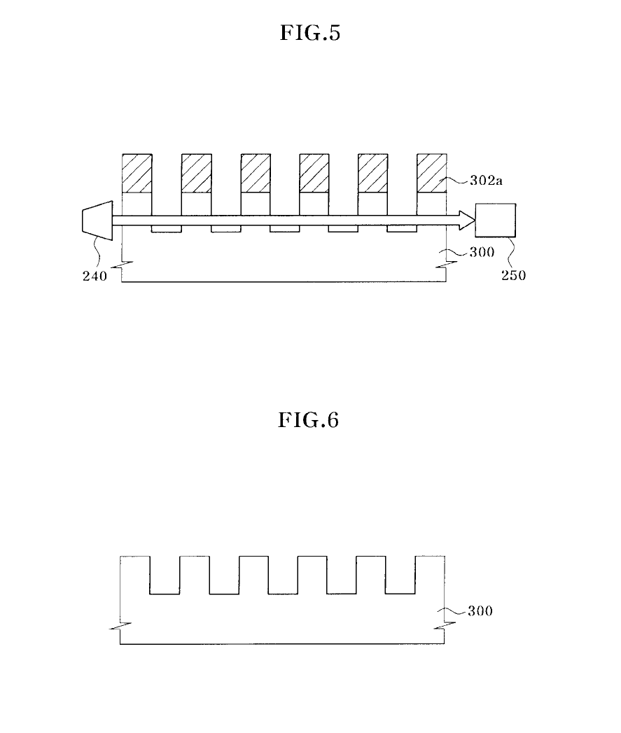

FIGS. 3 to 6 are cross-sectional views illustrating a method for fabricating an alternating phase shift mask by using the etching apparatus according to an embodiment of the present invention.

Referring to FIG. 3, a light blocking layer 302 is formed on a transparent mask substrate 300, and a resist pattern 304 is formed on the light blocking layer 302 to define a pattern to be formed. The substrate 300 is made of a transparent material such as quartz or glass, which allows light to transmit therethrough. The light blocking layer 302 may be formed of a material capable of blocking light, for example, a chromium (Cr) layer, and serves as a hard mask in an etching process with respect to a subsequent substrate. For example, the resist pattern 304 can be formed by coating electron beam resist on the light blocking layer 302 by a predetermined thickness and then performing an electron beam exposure and development process with respect to the electron beam resist.

Referring to FIG. 4, after an exposed light blocking layer is etched by using the resist pattern (304 of FIG. 2) as a mask to form a light blocking pattern 302a, the resist pattern is removed. Then, an etching process is performed on the substrate 300 by using the light blocking pattern 302a as a mask to form a phase shift pattern. As shown in FIG. 4, the mask substrate 300 having the light blocking pattern 302a is loaded in the chamber (not shown) in which the light source 240 is installed at one side of the mask substrate 300 and the detector 250 is installed at the other side of the mask substrate 300 to detect the intensity of the light having transmitted through the mask substrate 300 after being emitted from the light source 240. The light source 240 and the detector 250 are located such that the transmission depth of the light emitted from the light source 240 is equal to or less than a desired depth by which the mask substrate 300 is to be etched. That is, when the mask substrate 300 is etched deeper than the depth by which the light emitted from the light source 240 transmits through the mask substrate 300, and change in the intensity of the light detected by the detector 250 reaches a predetermined level, an etch ending point can be determined and controlled.

The light irradiated from the light source 240 to the mask substrate 300 reaches the detector 250 after passing through the transparent region of the mask substrate 300. At this time, when the mask substrate 300 is not subjected to the etching process or the mask substrate 300 is not etched up to the depth by which the light source 240 is installed, there is almost no difference between the initial intensity I₀ of the light incident into the mask substrate 300 from the light source 240 and the intensity I_{f} of the light having reached the detector 250 after transmitting through the mask substrate 300. This is because the number of interfaces through which the light transmits is only two and the light transmittance of the quartz substrate 300 is very high. Furthermore, since the intensity of the light is less reduced while the light transmits the quartz substrate 300, the value at such a state can be determined as a reference value.

FIG. 5 is a cross-sectional view illustrating the mask substrate 300 etched by a predetermined depth. As the mask substrate 300 is continuously etched, the number of interfaces through which the light emitted from the light source 240 must transmit is increased, resulting in significant difference between the initial intensity I₀ of the light from the light source 240 and the intensity I_{f} of the light having reached the detector 250.

When the mask substrate 300 is etched by an appropriate depth during the etching process, the number of interfaces through which the light transmitting through the transverse section of the mask must transmit is increased by twice as many as the number of patterns. Thus, whenever the light passes through each interface, the intensity of the light is reduced due to scattering, reflection and the like. The intensity of the light when having passed through one interface is slightly reduced. However, as the patterns are formed, the intensity I_{f} of the light having finally reached the detector 250 after passing through the interfaces corresponding to twice as many as the number of the patterns is significantly reduced as compared with the initial intensity I₀. The intensity I_{f} of the light having reached the detector 250 can be expressed by Equation (1) below:

I_{f}=I₀−(A×I₀)2^{N}

where I₀ represents the intensity of the light incident into the mask, I_{f} represents the intensity of the light reached the detector after transmitting through the mask, A represents a coefficient by which the intensity of the light is reduced when passing through interfaces, and N represents the number of patterns.

The degree of etching can be calculated using the intensity of the light detected after transmitting through the mask substrate 300 and Equation (1), and the etch ending point can be calculated using the degree of etching. Then, when the etch ending point is fed back to the etching process and the mask substrate 300 is etched by the target depth, the etching process is automatically stopped.

Referring to FIG. 6, when the mask substrate 300 is etched by the desired depth, the etching process is stopped, the light blocking pattern 302a used as the hard mask is removed, and a cleaning process is performed on the mask substrate 300, thereby completing the fabrication of the alternating phase shift mask.

According to an embodiment of the present invention, the etched depth of the substrate can be accurately controlled, so that the alternating phase shift mask with accurate phase shift values can be fabricated and distribution of the phase shift values can be very strictly managed. Furthermore, etching and measurement can be performed in-situ in a single etching chamber without moving the substrate into another process chamber in order to measure the etched depth of the substrate. In addition, fabrication of the alternating phase shift mask can be facilitated by changing a desired etched depth according to light sources used for lithography.

Meanwhile, the embodiment of the present invention can be applied to various fields according to wavelengths of light sources used and transmittance of materials constituting patterns. For example, the embodiment of the present invention can be applied to fabrication of a photomask in a semiconductor field, fabrication of a mask, a display panel and a mold for patterning in a display field, and the like.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. An etching apparatus having an etching space including a chamber comprising:
a chuck in the etching space configured to be loaded with a transparent object for etching;
a light source configured to irradiate light onto an object when loaded on the chuck for etching; and
a detector configured to detect an intensity of the light from the light source having transmitted through an object loaded on the chuck, wherein the detected light is considered to determine a degree of etching when etching an object loaded on the chuck.

2. The etching apparatus of claim 1, wherein the light source and the detector are located at a position which is equal to or less than a target etching depth of the object to be etched.

3. The etching apparatus of claim 1, wherein the object to be etched comprises a transparent substrate for fabricating a photomask.

4. A method of fabricating an alternating phase shift mask, the method comprising:
forming a hard mask pattern over a mask substrate to define a phase shift pattern;
loading the mask substrate in an etching chamber comprising:
a light source installed at one side of the mask substrate; and
a detector installed at the other side thereof to detect light having transmitted through the mask substrate after being irradiated from the light source; and
forming the phase shift pattern by etching the mask substrate by a predetermined depth while detecting the light having transmitted through the mask substrate after being irradiated from the light source.

5. The method of claim 4, wherein the light source and the detector are located at a position which is equal to or less than a target etching depth of the object to be etched.

6. The method of claim 4, wherein the hard mask pattern comprises a chromium (Cr) layer.

7. The method of claim 4, wherein, when forming the phase shift pattern, the mask substrate is not etched when a difference between an intensity of the light having transmitted through the mask substrate and an initial intensity of the light exceeds a predetermined value.

8. The method of claim 7, wherein final intensity of the light I_{F} having reached the light detector is determined by the following formula: I_{F}=I₀−(A×I₀)×2^{N}, where
I0 is the intensity of the light incident into the mask substrate;
A is a coefficient by which the intensity of light is reduced when passing through interfaces; and
N is the number of patterns
